(19) United States
(12) Patent Application Publication
(10) Pub. No.: US 2023/0155034 A1
(43) Pub. Date: May 18, 2023

(54) THIN-FILM TRANSISTOR ELEMENT AND METHOD FOR MANUFACTURING THE SAME

(71) Applicant: KANEKA CORPORATION, Osaka (JP)

(72) Inventors: Hirofumi Inari, Osaka (JP); Hiroshi Yoshimoto, Osaka (JP); Masahito Ide, Osaka (JP); Takao Manabe, Osaka (JP)

(73) Assignee: KANEKA CORPORATION, Osaka (JP)

(21) Appl. No.: 18/157,082

(22) Filed: Jan. 20, 2023

Related U.S. Application Data
(63) Continuation of application No. PCT/JP21/26581, filed on Jul. 15, 2021.

(30) Foreign Application Priority Data
Jul. 22, 2020 (JP) 2020-125120

(51) Int. Cl. H01L 29/786; H01L 29/417; H01L 29/66

(52) U.S. Cl. CPC H01L 29/7869; H01L 29/41733; H01L 29/66742

(57) ABSTRACT

A thin-film transistor element including a gate layer, an oxide semiconductor thin-film, a gate insulating film disposed between the gate layer and the oxide semiconductor thin-film, a pair of source-drain electrodes electrically connected to the oxide semiconductor thin-film, and a resin film covering the oxide semiconductor thin-film is provided. The oxide semiconductor thin-film contains two or more metal elements selected from indium, gallium, zinc, and tin. The resin film is in contact with the oxide semiconductor thin-film. The resin film may include a compound that contains a SiH group. The resin film may be formed by applying a composition including a SiH group-containing compound onto the oxide semiconductor thin-film, and heating the composition.

### TECHNICAL FIELD

One or more embodiments of the present disclosure relate to a thin-film transistor element and a method for manufacturing the thin-film transistor element.

### BACKGROUND

A thin-film transistor (TFT) using an oxide semiconductor such as InGaZnO has higher electron mobility over an amorphous silicon TFT, and excellent electrical characteristics, and therefore is expected as a drive element or a power-saving element for organic light emitting (OLED) displays. Like a conventional thin-film transistor using amorphous silicon, a thin-film transistor using an oxide semiconductor may have an insulating protective film disposed on a semiconductor thin-film for protecting the semiconductor thin-film from an external atmosphere, from the viewpoint of, for example, improving the operation stability of a device. For example, Japanese Patent Application Laid-Open No. 2013-89971 proposes that a photosensitive composition including a siloxane resin is applied onto an oxide semiconductor thin-film, patterned by photolithography, and then cured by heating to form a protective film.

A TFT element using an oxide semiconductor has high electron mobility, but development of an element having higher electron mobility is required from the viewpoint of improving a switching speed and saving power.

### SUMMARY

One or more embodiments of the present disclosure are a thin-film transistor element including a gate layer, an oxide semiconductor thin-film, a gate insulating film disposed between the gate layer and the oxide semiconductor thin-film, a pair of source/drain electrodes being in contact with the oxide semiconductor thin-film, and a resin film covering the oxide semiconductor thin-film. The resin film covering an oxide semiconductor thin-film may contain a compound having a SiH group.

The thin-film transistor element may be a bottom gate-type thin-film transistor element including a gate insulating film covering a gate layer, and an oxide semiconductor thin-film on the gate insulating film, or may be a top gate-type thin-film transistor element including a gate insulating film on an oxide semiconductor thin-film, and a gate layer on the gate insulating film. The oxide semiconductor thin-film contains two or more metal elements selected from the group consisting of In, Ga, Zn and Sn. Examples of the oxide include InGaZnO and InGaZnSnO.

In manufacturing of a thin-film transistor element, a composition including a SiH group-containing compound is applied onto an oxide semiconductor thin-film, and then heated to form a resin film being in contact with the oxide semiconductor thin-film. The heating temperature during formation of the resin film may be 190 to 450° C. The amount of SiH groups in the SiH group-containing compound may be 0.1 mmol/g or more. The SiH group-containing compound may be a polymer or may include a polysiloxane structure.

The composition used for forming the resin film may be a positive or negative photosensitive composition. The resin film formed from the photosensitive composition may be patterned by photolithography to form a contact hole. The composition may be a photocurable/thermosetting composition or a thermosetting composition that does not have alkali-solubility (photographic properties). The SiH group of the SiH group-containing compound may remain unreacted in the resin film cured by heat and/or light.

The thin-film transistor element may have an electron mobility of 35 cm²/Vs or more.

### BRIEF DESCRIPTION OF THE DRAWINGS

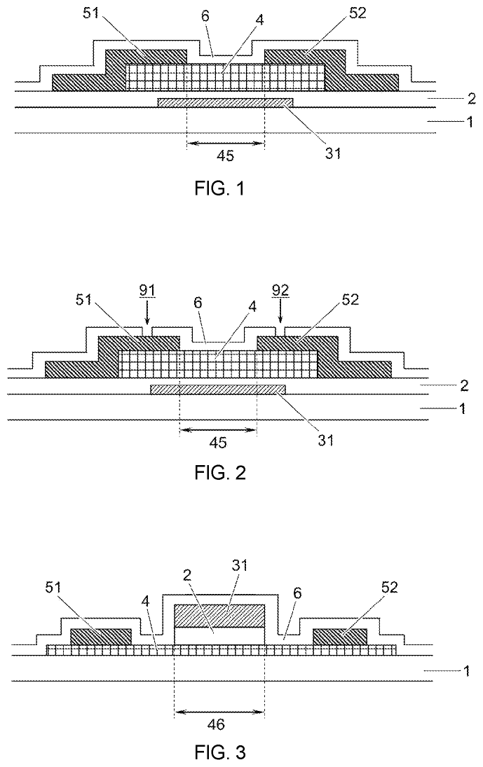

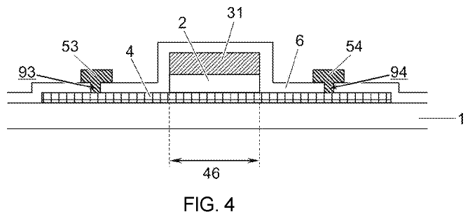

Each of FIGS. 1 and 2 is a sectional view showing an example of configuration of a bottom gate-type thin-film transistor element; and each of FIGS. 3 and 4 is a sectional view showing an example of configuration of a top gate-type thin-film transistor element.

### DETAILED DESCRIPTION

[Outline of Thin-Film Transistor Element]

FIG. 1 is a sectional view showing an example of configuration of a thin-film transistor element. The element shown in FIG. 1 is a bottom gate-type element in which a gate insulating film 2 is formed on a gate layer 31, and an oxide semiconductor thin-film 4 is formed on the gate insulating film 2. At both ends of the oxide semiconductor thin-film 4, a pair of source/drain electrodes 51 and 52 are formed so as to be in contact with the gate insulating film 2.

In production of the thin-film transistor element shown in FIG. 1, first, the gate layer 31 is formed on a substrate 1 such as glass, and the gate insulating film 2 is formed on the gate layer 31. Examples of the material for the gate layer 31 include metal materials such as molybdenum, aluminum, copper, silver, gold, platinum, titanium, and alloys thereof. As the gate insulating film 2, for example, a silicon-based thin-film such as a silicon oxide film, a silicon nitride film or a silicon nitride oxide film is formed by a plasma CVD method. The thickness of the gate insulating film is usually 50 to 300 nm. As the gate layer with an insulating film, a low-resistance silicon substrate in which a thermally oxidized film is formed on a surface of a silicon substrate may be used.

The oxide semiconductor thin-film 4 is a semiconductor thin-film including a composite oxide containing two or more metal elements among indium, gallium, zinc, and tin. The two or more metal elements forming the composite oxide of the oxide semiconductor thin-film 4 contain tin as an essential component, and may further contain one or more of indium, gallium, and zinc. Specific examples of the oxide include zinc-based oxides such as Zn—Ga—O and Zn—Sn—O, and indium-based oxides such as In—Zn—O, In—Sn—O, In—Zn—Sn—O, In—Ga—Sn—O, In—Ga—Zn—O, and In—Ga—Zn—Sn—O. The oxide may contain a metal element other than In, Ga, Zn, and Sn (e.g., Al or W).

The oxide semiconductor thin-film can be formed by a sputtering method, a liquid phase method or the like. The thickness of the oxide semiconductor thin-film is about 20 to 150 nm. It is preferable to perform heat annealing after formation of the oxide semiconductor thin-film 4 and before formation of a resin film 6 to be described later. The heat annealing may be performed after formation of the source/drain electrodes 51 and 52 on the oxide semiconductor thin-film 4. The heat annealing of the oxide semiconductor thin-film may be performed, for example, at 200 to 400° C. for about 10 minutes to 3 hours in an oxygen atmosphere.

The source/drain electrodes 51 and 52 are formed on the oxide semiconductor thin-film 4. The source/drain electrodes are formed so as to be electrically connected to the end portions of the oxide semiconductor thin-film 4, and a channel region 45 free of an electrode is formed between a pair of source/drain electrodes 51 and 52. Examples of the material for the source/drain electrode include molybdenum, aluminum, copper, silver, gold, platinum, titanium, and alloys thereof. The source/drain electrode may be a single layer or may include two or more layers.

Examples of the method for patterning the source/drain electrodes 51 and 52 include patterning by wet etching or dry etching, and patterning by masking deposition or lift-off.

A resin film 6 is formed so as to cover the oxide semiconductor thin-film 4. The resin film 6 has a role of protecting the oxide semiconductor thin-film 4 from an external environment and/or process damage. For example, in one or more embodiments shown in FIG. 1, the resin film 6 is formed so as to cover the source/drain electrodes 51 and 52, and functions as a protective film for protecting the oxide semiconductor thin-film 4 from an external environment.

A resin film may be formed between the oxide semiconductor thin-film 4 and the source/drain electrodes 51 and 52. In this case, the resin film can function as an etch stopper that prevents damage to the oxide semiconductor thin-film 4 when the source and drain electrodes are patterned. When a resin film is formed as an etch stopper, a source/drain electrode may be formed on the resin film after the resin film is formed.

The composition used for forming the resin film contains a compound having a SiH group (SiH group-containing compound). The amount of SiH groups in the SiH group-containing compound may be 0.1 mmol/g or more. The SiH group-containing compound may be a polymer. The composition may be a composition which has negative or positive photosensitivity, and can be patterned by photolithography. The composition may be a photocurable/thermosetting composition or a thermosetting composition that does not have alkali-solubility (photolithographic property).

A composition including a SiH group-containing compound is applied onto the oxide semiconductor thin-film 4, and the applied composition is heated to form the resin film 6. In the bottom gate-type element, it is preferable that a composition including a SiH group-containing compound is directly applied onto the channel region 45 of the oxide semiconductor thin-film 4, from the viewpoint of more effectively improving the characteristics of the thin-film transistor element. When a plurality of resin films are formed, it is preferable that the composition that contains a SiH group-containing compound is used for forming the resin film that is in contact with the channel region 45 of the oxide semiconductor thin-film 4.

The heating temperature during formation of the resin film may be 190° C. or higher. Heating of the composition may be performed in two or more stages. For example, first heating (pre-baking) for removing the solvent mainly contained in the composition and second heating (post-baking) for heat-curing the resin component may be performed. When heating is performed in two or more stages, the highest temperature may be 190° C. or higher. When the composition is photosensitive, exposure may be performed between pre-baking and post-baking.

When the composition including a SiH group-containing compound is heated on the oxide semiconductor thin-film 4, the electron mobility of the thin-film transistor element tends to be improved. The electron mobility of the thin-film transistor element may be 35 cm²/Vs or more, 40 cm²/Vs or more, 45 cm²/Vs or more, 50 cm²/Vs or more, 55 cm²/Vs or more, or 60 cm²/Vs or more.

Among oxide semiconductors, thin-film transistor elements using an In—Ga—Zn—O (IGZO) thin-film or an In—Ga—Zn—Sn—O (IGZTO) thin-film are known to have high electron mobility, but the value thereof is at most about 10 to 25 cm²/Vs. In one or more embodiments of the present disclosure, it is possible to provide a thin-film transistor element which can exhibit significantly higher electron mobility over a conventional oxide semiconductor thin-film transistor element, and is excellent in characteristics such as a switching speed.

The electron mobility of the element tends to increase as the amount of SiH groups in the composition increases and the heating temperature becomes higher. Although the reason why formation of a resin film results in considerable improvement of electron mobility is uncertain, one possible factor is diffusion of hydrogen generated from the SiH group-containing compound into the oxide semiconductor thin-film, in addition to the heat annealing of the oxide semiconductor thin-film. during heating. Diffusion of hydrogen generated from the SiH group remaining unreacted after heating (after curing) into the oxide semiconductor thin-film, passivation of the oxide semiconductor thin-film by the SiH group, and the like may also contribute to improvement of electron mobility.

[SiH Group-Containing Compound]

The SiH group-containing compound contains at least one SiH group in the molecule, and may include a polysiloxane structure. The “polysiloxane structure” means a structural skeleton having a siloxane unit (Si—O—Si). The polysiloxane structure may be a cyclic polysiloxane structure. The term “cyclic polysiloxane structure” means a cyclic molecular structure skeleton having a siloxane unit (Si—O—Si) in a structural element of a ring.

The amount of SiH groups contained in the SiH group-containing compound may be 0.1 mmol/g or more, 0.3 mmol/g or more, 0.5 mmol/g or more, 0.7 mmol/g or more, or 1.0 mmol/g or more. The upper limit of the amount of SiH groups contained in the SiH group-containing compound is not particularly limited, and is typically 30 mmol/g or less, and may be 20 mmol/g or less, 15 mmol/g or less, or 10 mmol/g or less.

The SiH group-containing compound may be a low-molecular-weight compound, or a polymer. Examples of the low-molecular-weight compound having a SiH group include polysiloxane compounds having a SiH group.

From the viewpoint of film formability and heat resistance of the resin film, the SiH group-containing compound may be a polymer having a polysiloxane structure. The composition for forming the resin film may contain both a low-molecular-weight compound having a SiH group and a polymer having a SiH group. The polysiloxane polymer may have a polysiloxane structure in the main chain or in the side chain. When the polymer has a polysiloxane structure in the main chain, the heat resistance of the resin film tends to be improved.

The polysiloxane polymer having a SiH group is obtained by, for example, a hydrosilylation reaction between (a) a polysiloxane compound having at least two SiH groups in one molecule and ((3) a compound having at least two carbon-carbon double bonds (ethylenically unsaturated groups) reactive with a SiH group in one molecule. Since a plurality of compounds (a) are crosslinked by the reaction between the compound (α) having a plurality of SiH groups and the compound having a plurality of ethylenically unsaturated groups, the molecular weight of the polymer tends to be increased, resulting in improvement of film formability and the heat resistance of the resin film.

(Compound (α): Polysiloxane Compound Having SiH Groups)

Specific examples of the polysiloxane compound (α) having at least two SiH groups in one molecule include hydrosilyl group-containing polysiloxanes having a linear structure, polysiloxanes having a hydrosilyl group at a molecular terminal, and cyclic polysiloxanes containing a hydrosilyl group. A polymer including a cyclic polysiloxane structure tends to be superior in film formability and heat resistance of a resin film to a polymer including only a chain polysiloxane structure.

The cyclic polysiloxane may have a polycyclic structure, and the polycyclic ring may have a polyhedral structure. For forming a film having high heat resistance and mechanical strength, it is preferable that a cyclic polysiloxane compound having at least two SiH groups in one molecule is used as the compound (α). The compound (α) may contain three or more SiH groups in one molecule. From the view point of heat resistance and light resistance, an atomic group attached to Si atom may be either a hydrogen atom or a methyl group.

Examples of the hydrosilyl group-containing polysiloxane having a linear structure include a copolymers of a dimethylsiloxane unit with a methylhydrogensiloxane unit and a terminal trimethylsiloxy unit, copolymers of a diphenylsiloxane unit with a methylhydrogensiloxane unit and a terminal trimethylsiloxy unit, copolymers of a methylphenylsiloxane unit with a methylhydrogensiloxane unit and a terminal trimethylsiloxy unit, and polysiloxanes terminally blocked with a dimethylhydrogensilyl group.

Examples of the polysiloxane having a hydrosilyl group at a molecular terminal include polysiloxanes terminally blocked with a dimethylhydrogensilyl group, and polysiloxanes including a dimethylhydrogensiloxane unit (H(CH₃)₂SiO_{1/2} unit) and at least one siloxane unit selected from the group consisting of a SiO₂ unit, a SiO_{3/2} unit and a SiO unit.

Examples of the cyclic polysiloxane compound include 1,3,5,7-tetrahydrogen-1,3,5,7-tetramethylcyclotetrasiloxane, 1-propyl-3,5,7-trihydrogen-1,3,5,7-tetramethylcyclotetrasiloxane, 1,5-dihydrogen-3,7-dihexyl-1,3,5,7-tetramethylcyclotetrasiloxane, 1,3,5-trihydrogen-1,3,5-trimethylcyclosiloxane, 1,3,5,7,9-pentahydrogen-1,3,5,7,9-pentamethylcyclosiloxane, and 1,3,5,7,9,11-hexahydrogen-1,3,5,7,9,11-hexamethylcyclosiloxane.

The compound ( ) may be a polycyclic polysiloxane. A polycyclic ring may be a polyhedral structure. In a polysiloxane having a polyhedron skeleton, the number of Si atoms forming a polyhedron skeleton may be 6 to 24, or 6 to 10. A specific example of a polysiloxane having a polyhedron skeleton is a silsesquioxane. The cyclic polysiloxane may be a silylated silicic acid having a polyhedron skeleton.

(Compound (β): Compound Having Ethylenically Unsaturated Group)

The compound (β) has two or more carbon-carbon double bonds reactive with a SiH group in one molecule. Examples of the atomic group containing a carbon-carbon double bond reactive with a SiH group (hereinafter, may be simply referred to as “ethylenically unsaturated group” or “alkenyl group”) include a vinyl group, an allyl group, a methallyl group, an acrylic group, a methacryl group, a 2-hydroxy-3-(allyloxy) propyl group, a 2-allylphenyl group, a 3-allylphenyl group, a 4-allylphenyl group, a 2-(allyloxy) phenyl group, a 3-(allyloxy) phenyl group, a 4-(allyloxy) phenyl group, a 2-(allyloxy) ethyl group, a 2,2-bis (allyloxymethyl) butyl group, a 3-allyloxy-2,2-bis (allyloxymethyl) propyl group, and a vinyl ether group.

Specific examples of the compound (β) having two or more alkenyl group include diallyl phthalate, triallyl trimellitate, diethylene glycol bisallyl carbonate, trimethylolpropane diallyl ether, trimethylolpropane triallyl ether, pentaerythritol triallyl ether, pentaerythritol tetraallyl ether, 1,1,2,2-tetraallyloxyethane, diarylidene pentaerythritol, triallyl cyanurate, triallyl isocyanurate, diallyl monobenzyl isocyanurate, diallyl monomethyl isocyanurate, 1,2,4-trivinylcyclohexane, 1,4-butanediol divinyl ether, nonanediol divinyl ether, 1,4-cyclohexanedimethanol divinyl ether, triethylene glycol divinyl ether, trimethylolpropane trivinyl ether, pentaerythritol tetravinyl ether, diallyl ether of bisphenol S, divinylbenzene, divinylbiphenyl, 1,3-diisopropenylbenzene, 1,4-diisopropenylbenzene, 1,3-bis (allyloxy) adamantane, 1,3-bis (vinyloxy) adamantane, 1,3,5-tris (allyloxy) adamantane, 1,3,5-tris (vinyloxy) adamantane, dicyclopentadiene, vinylcyclohexene, 1,5-hexadiene, 1,9-decadiene, diallyl ether, bisphenol A diallyl ether, 2,5-diallylphenol allyl ether, and oligomers of these compounds, 1,2-polybutadiene (having a 1,2 ratio of 10 to 100%, or having a 1,2 ratio of 50 to 100%), allyl ether of novolac phenol, allylated polyphenylene oxide, and compounds obtained by substituting all glycidyl groups of a conventionally known epoxy resin with allyl groups. A compound in which an allyl group in the compound exemplified above is replaced by a (meth)acryloyl group (e.g., polyfunctional (meth)acrylate) is also suitable as the compound (β).

The compound (β) may be a polysiloxane compound having two or more alkenyl groups.

Examples of the cyclic polysiloxane compound having two or more alkenyl group include 1,3,5,7-tetravinyl-1,3,5,7-tetramethylcyclotetrasiloxane, 1-propyl-3,5,7-trivinyl-1,3,5,7-tetramethylcyclotetrasiloxane, 1,5-divinyl-3,7-dihexyl-1,3,5,7-tetramethylcyclotetrasiloxane, 1,3,5-trivinyl-1,3,5-trimethylcyclosiloxane, 1,3,5,7,9-pentavinyl-1,3,5,7,9-pentamethylcyclosiloxane, and 1,3,5,7,9,11-hexavinyl-1,3,5,7,9,11-hexamethylcyclosiloxane

The compound (β) may be a compound having an alkenyl group at a terminal and/or a side chain of a polymer chain, such as polyether, polyester, polyarylate, polycarbonate, polyolefin, polyacrylic acid ester, polyamide, polyimide or phenol-formaldehyde.

(Other Starting Material)

In addition to the compound (α) and the compound (β) described above, a compound having only one functional group involved in a hydrosilylation reaction in one molecule may be used as a starting material for the hydrosilylation reaction. The functional group involved in a hydrosilylation reaction is a SiH group or an alkenyl group. By using a compound containing only one functional group involved in a hydrosilylation reaction, a specific functional group can be introduced to a terminal of the polymer.

A compound having a photopolymerizable functional group may be used as a starting material for the hydrosilylation reaction. Examples of the photopolymerizable functional group include cationically polymerizable functional groups and radically polymerizable functional groups. The term “cationically polymerizable functional group” means a functional group that is polymerized and crosslinked by an acidic active substance generated from a photoacid generator, when being irradiated with active energy ray. Examples of the active energy ray include visible light, ultraviolet ray, infrared ray, X ray, α ray, β ray, γ ray, and the like. Examples of the cationically polymerizable functional group include an epoxy group, a vinyl ether group, an oxetane group, and an alkoxysilyl group. From the view point of photosensitivity, an epoxy group is preferable as the cationically polymerizable functional group. Among epoxy groups, from the view point of stability, an alicyclic epoxy group or a glycidyl group is preferable. In particular, an alicyclic epoxy group is excellent in photocationic polymerizability and thus is preferable.

When a compound having an alkenyl group and a cationically polymerizable functional group in one molecule is used as a starting material, a cationically polymerizable functional group can be introduced into a polymer. When the polymer has a cationically polymerizable functional group, improvement of mechanical strength and heat resistance of the resin film can be expected because the polymer is crosslinked by photocationic polymerization.

Specific examples of the compound having an alkenyl group and an epoxy group as a cationically polymerizable functional group in one molecule include vinyl cyclohexene oxide, allyl glycidyl ether, diallyl monoglycidyl isocyanurate, and monoallyl diglycidyl isocyanurate.

The polysiloxane polymer may have two or more cationically polymerizable functional groups in one molecule. When the polysiloxane polymer has two or more cationically polymerizable functional groups in one molecule, a cured product tends to have a high crosslinking density and improved heat resistance. Two or more cationically polymerizable functional groups contained in the polysiloxane polymer may be the same or two or more different functional groups.

The polysiloxane polymer may be alkali-soluble. By introducing an alkali-solubility imparting group into the polymer, alkali-solubility can be imparted. When the polymer has a photopolymerizable functional group and an alkali-solubility imparting group, the polymer can be used as a negative photosensitive resin because the polymer has solubility in alkali before photocuring, and is insoluble in alkali after photocuring. Examples of the alkali-solubility imparting group (acidic group) include phenolic hydroxy groups, carboxy groups, N-substituted isocyanuric acids, and N,N′-disubstituted isocyanuric acids. When a compound having an acidic group and having an alkenyl group and/or a SiH group is used as a starting material for the hydrosilylation reaction, an alkali-soluble polymer is obtained.

The polysiloxane polymer may be one in which a protecting group is eliminated in the presence of an acid to exhibit alkali-solubility. A polymer in which a protecting group is eliminated in the presence of an acid to exhibit alkali-solubility can be used as a positive photosensitive resin because the protecting group is detached (deprotected) by a reaction with an acid generated from a photoacid generator, so that alkali-solubility is enhanced.

Examples of the acidic group include phenolic hydroxy groups, carboxy groups, N-substituted isocyanuric acids, and N,N′-disubstituted isocyanuric acids. Examples of the protecting group for the phenolic hydroxy group include a tert-butoxycarbonyl group and a trialkylsilyl group. For example, the phenolic hydroxy group can be protected by a tert-butoxycarbonyl group by a reaction using a Boc-reagent. From the viewpoint of ease of deprotection by an acid, the alkyl group in the trialkylsilyl group as the protecting group for the phenolic hydroxy group may be an alkyl group having 1 to 6 carbon atoms, or a methyl group. The phenolic hydroxy group can be protected by a trimethylsilyl group by a reaction using a silylating agent such as hexamethyldisilazane or trimethylchlorosilane. The acidic groups (NH groups) of N-substituted isocyanuric acid and N, N′-disubstituted isocyanuric acid can also be protected by the same protecting group as that for the phenolic hydroxy group. Examples of the protecting group for a carboxylic acid include tertiary alkyl esters and acetals. Examples of the tertiary alkyl group in the tertiary alkyl ester of a carboxylic acid include a tert-butyl group, an adamantyl group, a tricyclodecyl group, and a norbornyl group.

When a compound having a structure with a protecting group that is to be detached in the presence of an acid and having an alkenyl group and/or a SiH group is used as a starting material for the hydrosilylation reaction, a polysiloxane polymer is obtained in which a protecting group is eliminated in the presence of an acid, so that alkali-solubility is exhibited.

(Hydrosilylation Reaction)

The order and the method of the hydrosilylation reaction are not particularly limited. In the hydrosilylation reaction, polymerization may be performed with all starting materials put in one pot, or the reaction may be carried out in multiple stages with raw materials put in two or more parts.

The ratio B/A between the total amount of alkenyl groups (A) and the total amount of SiH groups (B) in the starting material of the hydrosilylation reaction may be more than 1. In the hydrosilylation reaction, alkenyl groups react with SiH groups at a ratio of 1:1. When B/A is more than 1 and the amount of SiH groups is excessively larger than the amount of alkenyl groups, a polysiloxane polymer having unreacted SiH groups is obtained.

The electron mobility of the thin-film transistor element tends to increase as the amount of SiH groups in the polysiloxane polymer in the resin film 6 formed on the oxide semiconductor thin-film 4 increases. Thus, B/A may be 1.1 or more, 1.5 or more, 2 or more, 3 or more, or 5 or more. From the viewpoint of increasing the SiH group content of the polymer, B/A may be as large as possible. On the other hand, if the amount of unreacted remaining SiH groups is excessively large, the stability of the resin film may be deteriorated, and therefore B/A may be 30 or less, 20 or less, 15 or less, or 10 or less.

In a hydrosilylation reaction, a hydrosilylation catalyst such as a chloroplatinic acid, a platinum-olefin complex, or a platinum-vinylsiloxane complex may be used. A hydrosilylation catalyst and a promoter may be used in combination. Although not particularly limited, an amount of the hydrosilylation may be 10⁻⁸ to 10⁻¹ times, or 10⁻⁶ to 10⁻² times a total amount (number of moles) of alkenyl groups contained in the starting materials.

The temperature of the hydrosilylation reaction may be appropriately set, and may be 30 to 200° C., or 50 to 150° C. An oxygen volume concentration of a gas phase part in a hydrosilylation reaction may be 3% or less. From the view point of promoting the hydrosilylation reaction by adding oxygen, the gas phase part may contain about 0.1 to 3 vol % of oxygen.

A solvent may be used in the hydrosilylation reaction. Examples of the solvent include hydrocarbon-based solvents such as benzene, toluene, hexane, and heptane; ether-based solvents such as tetrahydrofuran, 1,4-dioxane, 1,3-dioxolane and diethyl ether; ketone-based solvents such as acetone and methyl ethyl ketone; halogen-based solvents such as chloroform, methylene chloride and 1,2-dichloroethane; and the like. Since distillation after a reaction is easy, toluene, tetrahydrofuran, 1,4-dioxane, 1,3-dioxolane or chloroform is preferable. A gelation inhibitor may be used, as necessary, in the hydrosilylation reaction.

The amount of SiH groups contained in the polysiloxane polymer may be 0.1 mmol/g or more, 0.3 mmol/g or more, 0.5 mmol/g or more, 0.7 mmol/g or more, or 1.0 mmol/g or more. The upper limit of the amount of SiH groups contained in the polymer is not particularly limited, and is typically 30 mmol/g or less, and may be 20 mmol/g or less, 15 mmol/g or less, or 10 mmol/g or less.

As described above, the amount of remaining SiH groups in the polymer can be adjusted to be within a desired range by adjusting the type of starting material and the ratio between the amount of SiH groups and the amount of alkenyl groups.

[Composition]

The composition used for forming the resin film on the oxide semiconductor thin-film may contain, a polymer free of a SiH group, a crosslinker, a thermosetting resin, a photoacid generator, a sensitizer, a solvent, and the like in addition to the SiH group-containing compound.

<Crosslinker>

The composition may contain a crosslinker that is reactive with the SiH group-containing compound. The crosslinker may be one that reacts by light, or reacts by heat.

For example, when a compound having two or more alkenyl groups in one molecule is used as a crosslinker, heating causes the alkenyl groups to undergo a hydrosilylation reaction with SiH groups of the SiH group-containing compound, so that a crosslinked structure is introduced. Specific examples of the compound having two or more alkenyl groups in one molecule include those exemplified above as the compound (β).

When the SiH group-containing compound has cationic polymerizability, use of a compound having two or more alkenyl groups in one molecule as a crosslinker enables the resin film to be cured because the SiH group-containing compound and the crosslinker are reacted with each other by exposure. The crosslinker having photocationic polymerizability may be a compound having two or more alicyclic epoxy groups in one molecule. Examples of the compound having two or more alicyclic epoxy groups in one molecule include 3,4-epoxycydohexylmethyl-3′,4′-epoxycydohexane carboxylate (“Celoxide 2021P” manufactured by Daicel), ε-caprolactone modified 3′,4′-epoxycyclohexylmethyl 3,4-epoxycyclohexane carboxylate (“Celoxide 2081” manufactured by Daicel), bis(3,4-epoxycyclohexylmethyl) adipate, an epoxy-modified chain siloxane compound of the following formula 51 (“X-40-2669” manufactured by Shin-Etsu Chemical Co., Ltd.), and an epoxy-modified cyclic siloxane compound of the following formula S2 (“KR-470” manufactured by Shin-Etsu Chemical Co., Ltd.).

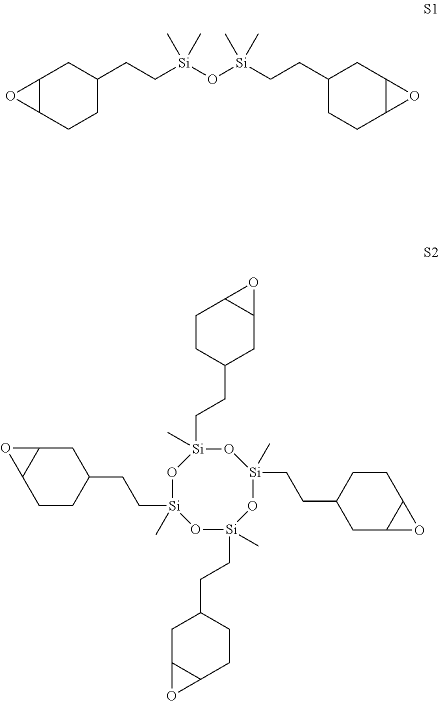 [SMILES: C[Si](C)(CCC1CCC2OC2C1)O[Si](C)(C)CCC1CCC2OC2C1 ; C[Si]1(CCC2CCC3OC3C2)O[Si](C)(CCC2CCC3OC3C2)O[Si](C)(CCC2CCC3OC3C2)O[Si](C)(CCC2CCC3OC3C2)O1]

<Thermosetting Resin>

The composition may contain a polymerizable compound (thermosetting resin) that is not reactive with the SiH group-containing compound and that can be heat-cured alone or by reacting with another compound. Examples of the thermosetting resin include epoxy resins, oxetane resins, isocyanate resins, blocked isocyanate resins, bismaleimide resins, bisallylnadiimide resins, acrylic resins, allyl cured resins, and unsaturated polyester resins. The thermosetting resin may be a side chain reactive group-type thermosetting polymer having a reactive group such as an allyl group, a vinyl group, an alkoxysilyl group or a hydrosilyl group in a side chain or a terminal of a polymer chain.

<Photoacid Generator>

The photosensitive composition for forming the resin film may contain a photoacid generator. When the photoacid generator is irradiated with an active energy ray such as an ultraviolet ray, an acid is generated. In a cationically polymerizable composition (e.g., a negative photosensitive composition), a photoacid generator acts as a polymerization initiator, so that curing by cationic polymerization proceeds. In a positive photosensitive composition, the protecting group bonded to an alkali-solubility imparting group (acidic group) is eliminated by the action of an acid generated from the photoacid generator, so that the alkali-solubility is enhanced.

The photoacid generator contained in the photosensitive composition is not particularly limited as long as it generates a Lewis acid when exposed. Specific examples of the photoacid generator include ionic photoacid generators such as sulfonium salts, iodonium salts, ammonium salts, and other onium salts; and nonionic photoacid generators such as imide sulfonates, oxime sulfonates and sulfonyl diazomethanes.

The content of the photoacid generator in the photosensitive composition may be 0.1 to 20 parts by weight, 0.1 to 15 parts by weight, or 0.5 to 10 parts by weight, based on 100 parts by weight of the resin content of the composition.

<Sensitizer>

The photosensitive composition for forming the resin film may contain a sensitizer. By using a sensitizer, the exposure sensitivity during patterning is improved. Examples of the sensitizer include naphthalene-based compounds, anthracene-based compounds, and thioxanthone-based compounds. Among them, anthracene-based sensitizers are preferable because they are excellent in photosensitizing effect. Specific examples of an anthracene-based compound include anthracene, 2-ethyl-9,10-dimethoxyanthracene, 9,10-dimethylanthracene, 9,10-dibutoxyanthracene (DBA), 9,10-dipropoxyanthracene, 9,10-diethoxyanthracene, 9,10-bis(octanoyloxy) anthracene, 1,4-dimethoxyanthracene, 9-methylanthracene, 2-ethylanthracene, 2-tert-butylanthracene, 2,6-di-tert-butylanthracene, and 9,10-diphenyl-2,6-di-tert-butylanthracene.

The content of the sensitizer in the composition is not particularly limited, and may be appropriately adjusted to the extent that a sensitizing effect can be exhibited. From the viewpoint of balance of the curability and the physical properties of the resin film, the content of the sensitizer may be 0.01 to 20 parts by weight, 0.1 to 15 parts by weight, or 0.5 to 10 parts by weight, based on 100 parts by weight of the resin content of the composition.

<Solvent>

The composition for forming the resin film can be prepared by dissolving or dispersing the above-described components in a solvent. The solvent may be any solvent that is capable of dissolving the above-mentioned SiH group-containing compound and other components. Specifically, examples of the solvent include hydrocarbon-based solvents such as benzene, toluene, hexane and heptane; ether-based solvents such as tetrahydrofuran, 1,4-dioxane, 1,3-dioxolane and diethyl ether; ketone-based solvents such as acetone, methyl ethyl ketone, methyl isobutyl ketone and cyclohexanone; glycol-based solvents such as propylene glycol-1-monomethyl ether-2-acetate (PGMEA), diethylene glycol dimethyl ether, diethylene glycol ethyl methyl ether and ethylene glycol diethyl ether; halogen-based solvents such as chloroform, methylene chloride and 1,2-dichloroethane; and the like. From the view point of film forming stability, propylene glycol-1-monomethyl ether-2-acetate and diethylene glycol dimethyl ether are preferable. An amount of a solvent t can be appropriately set.

<Other Components>

The composition for forming the resin film may contain a resin component or an additive other than the above-described components. For example, the composition for forming the resin film may contain various kinds of thermoplastic resins for a purpose of modifying characteristics of the photosensitive composition, etc. Examples of the thermoplastic resin include acrylic resins, polycarbonate-based resins, cycloolefin-based resins, olefin-maleimide-based resins, polyester-based resins, a polyether sulfone resin, a polyarylate resin, a polyvinyl acetal resin, a polyethylene resin, a polypropylene resin, a polystyrene resin, a polyamide resin, a silicone resin, a fluorine resin, and rubber-like resins such as a natural rubber and EPDM. The thermoplastic resin may have a crosslinkable group such as epoxy group, an amino group, a radically polymerizable unsaturated group, a carboxyl group, an isocyanate group, a hydroxy group and an alkoxysilyl group.

In addition to the above, the composition for forming the resin film may also contain an adhesion improver, a coupling agent (such as a silane coupling agent), a deterioration inhibitor, a radical inhibitor, a release agent, a flame retardant, a flame retardant aid, a surfactant, an antifoaming agent, an emulsifier, a leveling agent, a cis sing inhibitor, an ion trapping agent (such as antimony-bismuth), a thixotropic agent, a tackifier, a storage stability improver, an ozone deterioration inhibitor, a light stabilizer, a thickening agent, a plasticizer, a reactive diluent, an antioxidant, a heat stabilizer, a conductivity imparting agent, an antistatic agent, a radiation blocking agent, a nucleating agent, a phosphorus-based peroxide decomposing agent, a lubricant, a pigment, a metal deactivator, a thermal conductivity imparting agent, a physical property adjusting agent, and the like.

The amount of SiH groups in the resin content of the composition for forming the resin film may be 0.1 mmol/g or more, 0.3 mmol/g or more, 0.5 mmol/g or more, and may be 0.7 mmol/g or more or 1.0 mmol/g or more.

[Formation of Resin Film]

A composition including a SiH group-containing compound is applied onto the oxide semiconductor thin-film 4, and heated to form the resin film 6. As described above, it is preferable that the composition is directly applied onto the channel region 45 of the oxide semiconductor thin-film 4 in formation of the bottom gate-type element. The method for applying the composition is not particularly limited as long as the composition is uniformly applied, and a common coating method such as spin coating, slit coating, or screen coating can be used.

After the composition is applied, the resin film 6 is formed by heating. The thickness of the resin film 6 is, for example, about 0.2 to 6 and may be about 0.5 to 3

As described above, the heating temperature may be 190° C. or higher. The electron mobility of the element tends to increase as the heating temperature becomes higher. The heating temperature may be 200° C. or higher, 210° C. or higher, or 220° C. or higher. An excessively high heating temperature may cause thermal degradation of the oxide semiconductor thin-film or the resin film. Thus, the heating temperature may be 450° C. or lower, 400° C. or lower, 350° C. or lower, or 300° C. or lower. The heating time at a temperature of 190° C. or higher may be 5 minutes or more, or 10 minutes or more. The upper limit of the heating time is not particularly limited, and may be 5 hours or less, 3 hours or less, or 1 hour or less, from the viewpoint of suppression of thermal degradation and production efficiency. As described above, the heating of the composition may be performed in two or more stages.

Heating at 190° C. or higher causes the SiH groups of the SiH group-containing compound to react with each other, so that curing occurs. When the composition includes a compound having a plurality of alkenyl groups as a crosslinker, heating causes curing (crosslinking) to proceed under a hydrosilylation reaction between the SiH group and the alkenyl group of the crosslinking agent, and therefore the insulation quality, the heat resistance, the solvent resistance, and the like of the resin film tend to be improved.

When the resin film 6 is formed on the source/drain electrodes 51 and 52, contact holes 91 and 92 may be formed in the resin film 6 as shown in FIG. 2 for securing electrical connection to the source/drain electrodes 51 and 52. When the composition for forming the resin film has photosensitivity, it is preferable that before post-baking, exposure and alkali development are performed such that the resin film is patterned by photolithography.

Before the exposure, heating (pre-baking) may be performed for removing the solvent by drying. The heating temperature can be appropriately set, and the heating temperature may be 50 to 150° C. If the photosensitive composition including a thermosetting component is cured by heating, developability may be deteriorated. Thus, the heating temperature in the pre-baking may be 120° C. or lower.

The light source for exposure may be selected according to the sensitivity wavelength of the photoacid generator and the sensitizer contained in the photosensitive composition. In general, a light source with a wavelength in the range of 200 to 450 nm (e.g., a high pressure mercury lamp, an ultra-high pressure mercury lamp, a metal halide lamp, a high power metal halide lamp, a xenon lamp, a carbon arc lamp or a light emitting diode) is used.

The amount of exposure is not particularly limited, and may be 1 to 5000 mJ/cm², 5 to 1000 mJ/cm², or 10 to 500 mJ/cm². If the amount of exposure is excessively small, curing may be insufficient, resulting in deterioration of the pattern contrast, and if the amount of exposure is excessively large, the manufacturing cost may increase due to an increase in tact time.

In pattern exposure, a common photomask can be used. In the negative photosensitive composition, a pattern mask capable of ensuring that portions where contact holes 91 and 92 are formed are shielded from light is used. In the positive photosensitive composition, a pattern mask is used in which openings are formed so as to selectively expose a portion where the contact holes 91 and 92 are formed.

An alkaline developer is brought into contact with the exposed coating film by an immersion method, a spray method or the like, so that the coating film is removed by dissolving to perform patterning. In the negative photosensitive composition, the exposed portion is photocured and does not have alkali-solubility, and therefore the film at the non-exposed portion is selectively removed by alkali development. In the positive photosensitive composition, the alkali-solubility is enhanced by the action of the acid generated by irradiating the photoacid generator with light, so that the film at the exposed portion is selectively removed.

As an alkali developer, those commonly used can be used without particular limitation. Specific examples of the alkali developer include organic alkali aqueous solutions such as a tetramethylammonium hydroxide (TMAH) aqueous solution and a choline aqueous solution, inorganic alkali aqueous solutions such as a potassium hydroxide aqueous solution, a sodium hydroxide aqueous solution, a potassium carbonate aqueous solution, a sodium carbonate aqueous solution and a lithium carbonate aqueous solution. An alkali concentration of the developer may be 0.01 to 25 wt %, 0.1 to 10 wt %, or 0.3 to 5 wt %. The developer may contain a surfactant or the like for the purpose of adjusting the dissolution rate or the like.

By performing the heating (post-baking) after the development, the resin film is cured, and the electron mobility of the element is improved. A method in which a negative or positive photosensitive composition is used and the contact holes 91 and 92 are formed by photolithography hardly causes damage to the electrodes 51 and 52 and the oxide semiconductor thin-film 4 during formation of the contact holes, and can contribute to formation of an element having excellent characteristics.

The method for forming a contact hole is not limited to photolithography, and the contact hole may be formed by a method such as dry etching, mechanical drilling, laser processing, or lift-off. Depending on a structure of the element, it is not necessarily required to form a contact hole in the resin film. When patterning by photolithography is not required, the composition for forming the resin film may be a photocurable/thermo setting composition or a thermosetting composition having no alkali-solubility.

The SiH group of the SiH group-containing compound may remain unreacted in the resin film cured by heat and/or light. The amount of SiH groups in the cured resin film may be 0.001 mmol/g or more, 0.01 mmol/g or more, or 0.05 mmol/g or more.

As described above, in one or more embodiments, the composition including a SiH group-containing compound is applied onto an oxide semiconductor thin-film and heated to form a resin film, thereby obtaining a thin-film transistor element having high electron mobility. The configuration of the thin-film transistor element is not limited to the form shown in FIGS. 1 and 2. For example, a function as an etch stopper can be imparted by forming a resin film on the oxide semiconductor thin-film before formation of the source/drain electrodes 51 and 52 as described above. One or more embodiments are also applicable to a thin-film transistor element in which a source/drain electrode contacts an oxide semiconductor thin-film through a contact hole that is formed in a resin film.

The thin-film transistor element is not limited to a bottom gate type in which a gate layer is disposed on a side closer to the substrate than the semiconductor layer. The thin-film transistor element may be a top gate type in which a gate layer is disposed on top (i.e., a surface opposite to the substrate) of a semiconductor layer.

FIG. 3 is a sectional view showing an example of a configuration of a top gate type thin-film transistor element, where the oxide semiconductor thin-film 4 is disposed on the substrate 1, and the gate insulating film 2 and the gate layer 31 are disposed in a region on a part of the oxide semiconductor thin-film 4 to form the channel region 46. Although the gate layer 31 is disposed on the entire gate insulating film 2 in one or more embodiments shown in FIG. 3, the gate layer may be disposed in a region on a part of the gate insulating film. On the oxide semiconductor thin-film 4, source/drain electrodes 51 and 52 are arranged separately from the gate layer 31. The source/drain electrodes 51 and 52 are separated from the gate layer 31, and may be in contact with the gate insulating film 2. The materials, formation methods, thicknesses and the like for the gate insulating film 2, the gate layer 31, the oxide semiconductor thin-film 4 and the source/drain electrodes 51 and 52 are the same as those for the aforementioned bottom gate type.

Even in the top gate-type element, the characteristics (e.g., electron mobility) of the thin-film transistor element tend to be improved when a composition including a SiH group-containing compound is applied so as to cover the oxide semiconductor thin-film 4, and then heated to form the resin film 6. In this configuration, the resin film 6 functions not only as a protective film for the oxide semiconductor thin-film 4 but also as an interlayer insulating film that insulates electrodes from each other.

In the top gate-type element shown in FIG. 3, although the resin film 6 is not in contact with the oxide semiconductor thin-film 4 in the channel region 46, as in the case of the bottom gate-type element, the characteristics of the thin-film transistor element are improved by forming the resin film 6 using a composition having SiH. Although the reason for this is uncertain, the improvement of the characteristics may be due to the fact that there is an effect of improving film quality as a bulk of the oxide semiconductor thin-film 4 by forming the resin film 6 in a region on a part of the oxide semiconductor thin-film 4, hydrogen generated from the SiH group-containing compound of the resin film 6 is diffused even to a region which is not in contact with the resin film 6 of the oxide semiconductor thin-film 4, thereby contributing to the improvement of film quality, and so on.

In the top gate-type element, the resin film 6 only needs to cover the oxide semiconductor thin-film 4 in regions between the electrode 51 and the gate layer 31 and between the electrode 52 and the gate layer 31, and the resin film 6 is not required to be provided in a part or the whole of the regions of the source/drain electrodes 51 and 52 and a part or the whole of the regions on the gate layer 31. For example, as in the case shown in FIG. 2, a contact hole may be formed in the resin film 6 on the source/drain electrodes 51 and 52. As in one or more embodiments shown in FIG. 4, the resin film 6 may be formed, followed by forming contact holes 93 and 94 in the resin film 6, and forming source/drain electrodes 53 and 54 so as to contact the oxide semiconductor thin-film 4 through the contact holes.

The thin-film transistor element may have a double gate structure in which a bottom gate layer closer to the substrate than the semiconductor layer and a top gate layer disposed on the semiconductor layer (a surface opposite to the substrate) are provided. The double gate-type element includes a bottom gate insulating film between the semiconductor layer and the bottom gate layer, a top gate insulating film between the semiconductor layer and the top gate layer, and the resin film being in contact with the semiconductor layer. The double gate-type element can be manufactured by, for example, sequentially forming a bottom gate layer, a bottom gate insulating film and a semiconductor layer on a substrate as in formation of the bottom gate-type element, and then forming a top gate insulating film, a top gate layer and a resin film (interlayer filling film) on the semiconductor layer as in formation of the top gate-type element.

### EXAMPLES

Hereinafter, one or more embodiments of the present disclosure will be described more in detail on the basis of examples, but one or more embodiments of the present disclosure are not limited to examples below.

[Synthesis of Polysiloxane Polymer]

### Synthesis Example 1

40 g of diallylisocyanuric acid and 29 g of diallylmonomethylisocyanuric acid were dissolved in 264 g of dioxane, and 0.02 g of a xylene solution of a platinum vinyl siloxane complex (“Pt-VTSC-3X” manufactured by Umicore Precious Metals Japan Co., Ltd., platinum content: 3 wt %) was added to prepare a solution 1. A solution obtained by dissolving 88 g of 1,3,5,7-tetrahydrogen-1,3,5,7-tetramethylcyclotetrasiloxane in 176 g of toluene was heated to 105° C., and the solution 1 was added dropwise over 3 hours in a nitrogen atmosphere containing oxygen at 3%. 30 minutes after the end of the dropwise addition, the reaction ratio of alkenyl groups was confirmed to be 95% or more by ¹H-NMR.

To the reaction solution, 124 g of a solution obtained by mixing 1-vinyl-3,4-epoxycyclohexane and toluene at a weight ratio of 1:1 (62 g of 1-vinyl-3,4-epoxycyclohexane) was added dropwise over 1 hour. 30 minutes after the end of the dropwise addition, the reaction ratio of alkenyl groups was confirmed to be 95% or more by ¹H-NMR. Thereafter, the reaction was completed by cooling, and toluene and dioxane were distilled off under reduced pressure to obtain a polymer A. The amount of SiH groups measured by ¹H-NMR was 1.1 mmol/g.

### Synthesis Example 2

Except that the dropwise addition amount of the toluene solution of 1-vinyl-3,4-epoxycyclohexane was changed to 160 g (addition amount of 1-vinyl-3,4-epoxycyclohexane was changed to 80 g), the same procedure as in Synthesis Example 1 was carried out to obtain a polymer B having SiH groups at 0.3 mmol/g.

### Synthesis Example 3

5 g of bisphenol was dissolved in 20 g of tetrahydrofuran (THF), 2.5 g of hexamethyldisilazane was then added, and the mixture was reacted at room temperature for 2 hours. THF and the reaction residue were distilled off under reduced pressure to obtain 6.5 g of a reaction product 2. The reaction product 2 was diallyl-bisphenol S with a hydroxy group protected by a trimethylsilyl group, and was confirmed to have no trimethylsilyl group-derived peak and no hydroxy group-derived peak by ¹H-NMR.

3 g of 1,3,5,7-tetrahydrogen-1,3,5,7-tetramethylcyclotetrasiloxane was dissolved in 20 g of toluene, a gas phase portion was washed with nitrogen, and the mixture was then heated to 100° C. To this solution, a mixed liquid containing 5 g of the reaction product 2, 1.5 g of 1,3,5,7-tetravinyl-1,3,5,7-tetramethylcyclotetrasiloxane, 0.7 mg of a xylene solution of a platinum vinyl siloxane complex (“Pt-VTSC-3X” manufactured by Umicore Precious Metals Japan Co., Ltd.) and 5 g of toluene was added dropwise over 45 minutes. 30 minutes after the end of the dropwise addition, the reaction ratio of alkenyl groups was confirmed to be 95% or more by ¹H-NMR. Thereafter, the reaction was completed by cooling, and toluene was distilled off under reduced pressure to obtain a polymer C which is a colorless and transparent liquid. The amount of SiH groups measured by ¹H-NMR was 3.0 mmol/g.

### Synthesis Example 4

72.4 g of 1,3,5,7-tetramethylcyclotetrasiloxane was dissolved in 72 g of toluene, a gas phase portion was washed with nitrogen, and the mixture was then heated to 105° C. To this solution, a mixed liquid containing 10 g of triallyl isocyanurate, 6.3 mg of a xylene solution of a platinum vinyl siloxane complex (“Pt-VTSC-3X” manufactured by Umicore Precious Metals Japan Co., Ltd.) and 10 g of toluene was added dropwise over 45 minutes. 60 minutes after the end of the dropwise addition, the reaction ratio of alkenyl groups was confirmed to be 95% or more by ¹H-NMR. Thereafter, the reaction was completed by cooling, and toluene was distilled off under reduced pressure to obtain a polymer D which is a colorless and transparent liquid. The amount of SiH groups measured by ¹H-NMR was 9.2 mmol/g.

[Preparation of Insulating Film Forming Composition]

Photocurable/thermosetting resin compositions 1 to 7 were prepared in accordance with the formulations (weight ratios) shown in Table 1. Compositions 1 and 2 are negative photosensitive compositions, Composition 3 is a positive photosensitive composition, and Composition 4 is a photocurable/thermosetting composition having no photolithographic property (alkali-solubility).

Composition 5 includes an acrylic resin exhibiting alkali-solubility (“PHOLET ZAH110” manufactured by Soken Chemical & Engineering Co., Ltd.) and an epoxy compound of the following formula (“CELLOXIDE 2021P” manufactured by Daicel Corporation) as resin components.

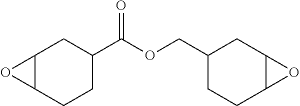 [SMILES: O=C(OCC1CCC2OC2C1)C1CCC2OC2C1]

Composition 6 includes an epoxy siloxane compound of the following formula (KR-470: “KR-470” manufactured by Shin-Etsu Chemical Co., Ltd.) as a resin component. Composition 7 includes triglycidyl isocyanurate (TEPIC) as a resin component.

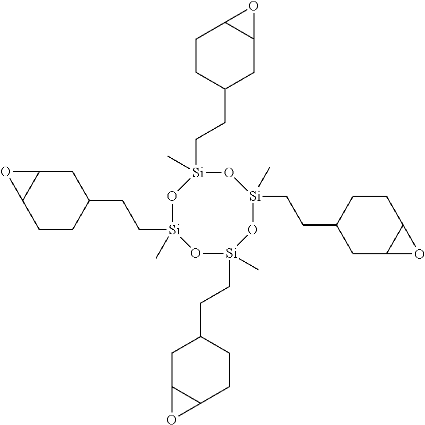 [SMILES: C[Si]1(CCC2CCC3OC3C2)O[Si](C)(CCC2CCC3OC3C2)O[Si](C)(CCC2CCC3OC3C2)O[Si](C)(CCC2CCC3OC3C2)O1]

Details of the components shown in Table 1 are as follows.

TALC: Triallyl isocyanurate

Photoacid generator: “CPI 210 S” (sulfonium salt-based photoacid generator) manufactured by San-Apro Ltd.

Sensitizer: 9,10-dibutoxyanthracene

Pt catalyst: “Pt-VTSC-3X” manufactured by Umicore Precious Metals Japan Co., Ltd.

Solvent: Propylene glycol monomethyl ether acetate

TABLE 1

| | | Composition for forming resin film | | | | | | |
|---|---|---|---|---|---|---|---|---|
| | | 1 | 2 | 3 | 4 | 5 | 6 | 7 |
| Component | Polymer A | 100 | — | — | — | — | — | — |
| | Polymer B | — | 100 | — | — | — | — | — |
| | Polymer C | — | — | 100 | — | — | — | — |
| | Polymer D | — | — | — | 60 | — | — | — |
| | Acrylic resin | — | — | — | — | 240 | — | — |
| | 2021P | — | — | — | — | 30 | — | — |
| | KR-470 | — | — | — | — | — | 100 | — |
| | TEPIC | — | — | — | — | — | — | 100 |
| | TAIC | — | — | 5 | 40 | — | — | — |
| | Photoacid generator | 2 | 2 | 2 | — | 2 | 2 | 2 |
| | Sensitizer | 2 | 2 | 2 | — | 2 | 2 | 2 |
| | Pt catalyst | — | — | 0.01 | 0.03 | — | — | — |
| | Solvent | 300 | 300 | 300 | 200 | 130 | 200 | 200 |

| | | | | | | | |
|---|---|---|---|---|---|---|---|
| SiH amount of polymer | 1.1 | 0.3 | 3.0 | 9.2 | 0 | 0 | 0 |
| (mmol/g) | | | | | | | |
| SiH amount in resin content | 1.1 | 0.3 | 2.9 | 5.5 | 0 | 0 | 0 |
| of composition | | | | | | | |
| (mmol/g) | | | | | | | |
| Photolithographic property | Negative- | Negative- | Positive- | None | None | None | None |
| | type | type | type | | | | |

[Production of IGZO Semiconductor Thin-Film Transistor Element]

### Reference Example 1: Bottom Gate-Type Element Having No Protective Film

On a p-type highly doped Si substrate with a 100 nm-thick thermally oxidized film, an oxide (IGZO) semiconductor thin-film having a thickness of 70 nm was formed by sputtering with an alloy target of In:Ga:Zn=2:2:1 under the conditions of a pressure of 0.6 Pa, an Ar flow rate of 19.1 sccm and an O₂ flow rate of 0.9 sccm by a sputtering device (“SENTRON” manufactured by EMIT SHIMADZU CORPORATION). A resist pattern was formed on the oxide semiconductor thin-film, wet etching was performed with 0.05 mol % hydrochloric acid, and the resist was then removed by washing with acetone and methanol to pattern the oxide semiconductor thin-film. A resist pattern was formed thereon, a Pt source electrode having a thickness of 20 nm and a Mo drain electrode having a thickness of 80 nm were formed by sputtering, and the electrodes were patterned by lift-off. Thereafter, heat annealing was performed at 290° C. for 1 hour under an oxygen flow (02 flow rate: 5 sccm) to obtain a bottom gate-type thin-film transistor element.

### Example 1 to 3

In the same manner as in Reference Example 1, an oxide semiconductor thin-film, a source electrode and a drain electrode were formed, patterned, and subjected to heat annealing. To a surface on which the oxide semiconductor thin-film and the electrodes are formed, each of the Compositions 1 to 3 of Table 1 was applied by spin coating so as to have a thickness of 1 μm after drying, and the applied composition was heated on a hot plate at 110° C. for 2 minutes. With a mask aligner (“MA-10” manufactured by Mikasa Co., Ltd.), exposure was performed (integrated amount of light: 100 mJ/cm²) through a photomask having a 100 μm hole pattern (negative pattern for Examples 1 and 2 and positive pattern for Example 3). Development treatment was performed with a 2.38% TMAH developer to form a 100 μm φ contact hole on each of the source electrode and the drain electrode. Thereafter, curing (post-baking) was performed by heating at 230° C. for 30 minutes to obtain a thin-film transistor element including a protective film.

### Example 4

As in Examples 1 to 3, to a surface on which the oxide semiconductor thin-film and the electrodes are formed, the Composition 4 of Table 1 was applied by spin coating so as to a thickness of 1 μm after drying, and the applied composition was heated on a hot plate at 110° C. for 2 minutes, and then cured by heating at 230° C. for 30 minutes. Thereafter, the protective films on the source electrode and the drain electrode were removed by dry etching to form contact holes.

### Comparative Examples 1 to 3

As in Examples 1 to 3, to a surface on which the oxide semiconductor thin-film and the electrodes are formed, the Compositions 5 to 7, respectively, of Table 1 was applied by spin coating so as to a thickness of 1 μm after drying, and the applied composition was heated on a hot plate at 110° C. for 2 minutes. Exposure without a photomask was performed using a mask aligner, and curing was then performed by heating at 230° C. for 30 minutes. Thereafter, as in Example 4, contact holes were formed by dry etching.

### Example 5 and Comparative Examples 4 and 5

Except that the post-baking temperature of the protective film was changed to those shown in Table 2, the same procedure as in Example 1 was carried out to obtain a thin-film transistor element including a protective film having contact holes.

### Reference Example 2: Top Gate-Type Element Having No Interlayer Insulating Film

On a Si substrate with a 100 nm-thick thermally oxidized film, an IGZO semiconductor thin-film having a thickness of 70 nm was formed and patterned under the same conditions as in Reference Example 1. A SiO₂ layer (gate insulating film) having a thickness of 200 nm and an Al layer (gate layer) having a thickness of 100 nm were sequentially formed by sputtering. A resist pattern was formed on the Al layer, the Al layer was wet-etched with a mixed acid (phosphoric acid at 80 wt %, nitric acid at 5 wt %, acetic acid at 5 wt %, and water as a balance), and the resist was then removed by washing with acetone and methanol. Thereafter, the SiO₂ layer was patterned by inductively coupled plasma reactive ion etching (ICP-RIE) using CF₄ as an etching gas, and Ar plasma treatment was performed. A resist pattern was formed, a Pt source electrode having a thickness of 20 nm and a Mo drain electrode having a thickness of 80 nm were formed by sputtering, and the electrodes were patterned by lift-off. Thereafter, heat annealing was performed at 290° C. for 1 hour under an oxygen flow (O₂ flow rate: 5 sccm) to obtain a top gate-type thin-film transistor element.

### Example 6

In the same manner as in Reference Example 2, an oxide semiconductor thin-film, a gate insulating film, a gate layer source electrode and a drain electrode were formed, patterned, and subjected to heat annealing. To a surface on which the oxide semiconductor thin-film and the electrodes are formed, the Composition 1 of Table 1 was applied by spin coating so as to have a thickness of 1 after drying, and the applied composition was heated on a hot plate at 110° C. for 2 minutes. Thereafter, formation of contact holes and post-baking (230° C. for 30 minutes) were performed under the same conditions as in Example 1 to obtain a thin-film transistor element including an interlayer insulating film.

### Comparative Example 6

As in Example 6, to a surface on which the oxide semiconductor thin-film and the electrodes are formed, the Composition 5 of Table 1 was applied by spin coating so as to a thickness of 1 μm after drying, and the applied composition was heated on a hot plate at 110° C. for 2 minutes. Exposure without a photomask was performed using a mask aligner, and curing was then performed by heating at 230° C. for 30 minutes. Thereafter, as in Example 4, contact holes were formed by dry etching.

[Evaluation]

By using a semiconductor parameter analyzer (“Agilent 4156” manufactured by Agilent Technologies), the current transfer characteristics of the thin-film transistor elements of Reference Examples, Examples and Comparative Examples were measured with the gate voltage changed within the range of −20 V to +20 V under the conditions of a drain voltage of 5 V and a substrate temperature at room temperature. The electron mobility, the threshold voltage and the ON/OFF current ratio were calculated by the following methods.

(Threshold Voltage)

The voltage value at an X intercept of a tangent line between saturation regions for the current transfer characteristics was taken as a threshold voltage Vₜₕ.

(Electron Mobility)

From the following calculating expression, the electron mobility μ in the gate voltage range of −20 V to +20 V was calculated, and the maximum value in the measurement range was taken as electron mobility of the element.

μ=2(L×I_{d})/{W×Cox×(V_{g}−Vₜₕ)²}
L: Channel length; 10 μm
W: Channel width: 90 μm
Cox: Capacitance per unit area of gate insulating film: 3.45×10⁻⁸ F/cm²
V_{g}: Gate voltage
Vₜₕ: Threshold voltage
I_{d}: Source-Drain Current

(ON/OFF Current Ratio)

In the current transfer characteristic curve, the maximum current value in the saturation region was taken as an ON-current Iₒₙ. An OFF-current I_{off} was determined from the minimum current in the off-state. The ratio Iₒₙ/I_{off} of both the currents was taken as an ON/OFF current ratio.

Tables 2 and 3 show the types of Compositions used for formation of the protective film, the amounts of SiH groups, the conditions for curing by heating (post-baking) during formation of the protective film, and the results of evaluation of the thin-film transistor element in Reference Examples, Examples and Comparative Examples.

TABLE 2

| | | Bottom gate | | | | | | | | | | |
|---|---|---|---|---|---|---|---|---|---|---|---|---|
| | | Refer- | | | | | Compar- | Compar- | Compar- | | Compar- | Compar- |
| | | ence | Exam- | Exam- | Exam- | Exam- | ative | ative | ative | Exam- | ative | ative |
| | | Example | ple | ple | ple | ple | Example | Example | Example | ple | Example | Example |
| | | 1 | 1 | 2 | 3 | 4 | 1 | 2 | 3 | 5 | 4 | 5 |
| Composition | | — | 1 | 2 | 3 | 4 | 5 | 6 | 7 | 1 | 1 | 1 |
| SiH amount of Composition | | — | 1.1 | 0.3 | 2.9 | 5.5 | 0 | 0 | 0 | 1.1 | 1.1 | 1.1 |
| (mmol/g) | | | | | | | | | | | | |
| Heating | Temperature | — | 230 | 230 | 230 | 230 | 230 | 230 | 230 | 200 | 150 | 180 |
| conditions of | (° C.) | | | | | | | | | | | |
| protective | Time | | 30 | 30 | 30 | 30 | 30 | 30 | 30 | 30 | 30 | 30 |
| film | (min.) | | | | | | | | | | | |
| Transistor | Threshold voltage | 1.4 | −0.7 | 1.1 | 1.5 | 0.4 | 0.8 | 1.8 | −0.7 | −0.5 | 0.5 | 0.2 |
| properties | (V) | | | | | | | | | | | |
| | Electron mobility | 13.8 | 58.3 | 35.8 | 36.4 | 48.7 | 19.7 | 7.8 | 12.1 | 44.8 | 17.5 | 23.6 |
| | (cm²/Vs) | | | | | | | | | | | |
| | ON/OFF ratio | 9.6 | 10.3 | 7.6 | 8.0 | 9.5 | 8.6 | 8.6 | 9.0 | 9.7 | 8.3 | 8.7 |

TABLE 3

| | | Top gate | | |
|---|---|---|---|---|
| | | Reference | | Comparative |
| | | Example | Example | Example |
| | | 2 | 6 | 6 |
| Composition | | — | 1 | 5 |
| SiH amount of Composition | | — | 1.1 | 0.0 |
| (mmol/g) | | | | |
| Heating | Temperature | — | 230 | 230 |
| conditions of | (° C.) | | | |
| protective | Time | | 30 | 30 |
| film | (min.) | | | |
| Transistor | Threshold voltage | −0.9 | −1.3 | −0.7 |
| properties | (V) | | | |
| | Electron mobility | 14.5 | 35.6 | 11.9 |
| | (cm²/Vs) | | | |
| | ON/OFF ratio | 8.3 | 8.7 | 7.9 |

The bottom gate-type thin-film transistor elements of Examples 1 to 4 in which the protection film was formed using a composition including a polysiloxane polymer having a SiH group had an electron mobility of 35 cm²/Vs or more, with the electron mobility being significantly higher than that of the element of Reference Example 1 in which a protective film was not formed. In Examples 1 to 4, the electron mobility of the element tended to increase as the amount of SiH groups in the protective film becomes larger.

Comparative Example 1 in which a protective film was formed using a composition free of SiH groups has exhibited higher electron mobility over Reference Example 1, but the electron mobility was less than 20 cm²/Vs. Comparative Examples 2 and 3 have exhibited the electron mobility lower than that in Reference Example 1.

The top gate-type thin-film transistor element of Example 6 has exhibited the electron mobility of 35 cm²/Vs or more as in Examples 1 to 4, with the electron mobility being significantly higher than that of the element of Reference Example 2 in which an interlayer insulating film was not formed. The element of Comparative Example 6 in which the interlayer insulating film was formed using a composition free of SiH groups had electron mobility lower than that in Reference Example 2.

The element of Example 5 in which a composition identical to that in Example 1 was used and the temperature during heat-curing was changed to 200° C. had electron mobility lower than that in Example 1, but had significantly higher element mobility over Reference Example 1. Comparative Example 4 in which the heat-curing temperature was 150° C. and Comparative Example 5 in which the heat-curing temperature was 180° C. had higher electron mobility over Reference Example 1, but did not exhibit a significant increase in electron mobility as in Examples 1 and 5.

From the above results, it can be seen that when a resin composition containing a SiH group is applied onto an oxide semiconductor thin-film, and heated at a high temperature, the electron mobility of the element is improved in both the top gate-type element and the bottom gate-type element. When the amount of SiH groups contained in the resin composition was larger and the heating temperature was higher, the electron mobility was more significantly improved.

[Production of IGZTO Semiconductor Thin-Film Transistor Element]

### Reference Example 3: Bottom Gate-Type Element Having No Protective Film

On a p-type highly doped Si substrate with a 100 nm-thick thermally oxidized film, an oxide (IGZTO) semiconductor thin-film having a thickness of 30 nm was formed by sputtering with an alloy target of In, Ga, Zn and Sn under the conditions of a pressure of 0.5 Pa, an Ar flow rate of 2.0 sccm and an O₂ flow rate of 2.0 sccm by a sputtering device (“SENTRON” manufactured by EMIT SHIMADZU CORPORATION). A resist pattern was formed on the oxide semiconductor thin-film, wet etching was performed with 0.05 mol % hydrochloric acid, and the resist was then removed by washing with acetone and methanol to pattern the oxide semiconductor thin-film. A substrate in which a patterned oxide semiconductor thin-film is provided on a Si substrate was subjected to heat annealing at 400° C. for 1 hour in the air. A resist pattern was formed on the oxide semiconductor thin-film-formed surface of the substrate, a Pt source electrode having a thickness of 20 nm and a Mo drain electrode having a thickness of 80 nm were formed by sputtering, and the electrodes were patterned by lift-off. Thereafter, heat annealing was performed at 350° C. for 1 hour under an oxygen flow to obtain a bottom gate-type thin-film transistor element.

### Example 7 and Comparative Example 7

In the same manner as in Reference Example 3, an oxide semiconductor thin-film, a source electrode and a drain electrode were formed, patterned, and subjected to heat annealing. Thereafter, using the Compositions 1 and 5 in Table 1, thin-film transistor elements including a protective film were produced in the same manner as in Example 1 and Comparative Example 1, respectively.

### Reference Example 4: Top Gate-Type Element Having No Interlayer Insulating Film

Except that as a semiconductor thin-film, an IGZTO semiconductor thin-film having a thickness of 30 nm was formed in place of the IGZO semiconductor having a thickness of 70 nm, the same procedure as in Reference Example 2 was carried out to obtain a top gate-type thin-film transistor element. The IGZTO semiconductor thin-film was formed under the same conditions as in Reference Example 3.

### Example 7 and Comparative Example 7

In the same manner as in Reference Example 4, an oxide semiconductor thin-film, a gate insulating film, a gate layer source electrode and a drain electrode were formed, patterned, and subjected to heat annealing. Thereafter, using the Compositions 1 and 5 in Table 1, thin-film transistor elements including an interlayer insulating film were produced in the same manner as in Example 6 and Comparative Example 6, respectively.

[Evaluation]

The current transfer characteristics of the elements of Reference Examples 3 and 4, Examples 7 and 8 and Comparative Examples 7 and 8 were measured, and the electron mobility, the threshold voltage and the ON/OFF current ratio were calculated. Table 4 shows the types of Compositions used for formation of the protective film, the amounts of SiH groups, the conditions for curing by heating (post-baking) during formation of the protective film, and the results of evaluation of the thin-film transistor element.

TABLE 4

| | | Bottom gate | | | Top gate | | |
|---|---|---|---|---|---|---|---|
| | | Reference | | Comparative | Reference | | Comparative |
| | | Example | Example | Example | Example | Example | Example |
| | | 3 | 7 | 7 | 4 | 8 | 8 |
| Composition | | — | 1 | 5 | — | 1 | 5 |
| SiH amount of Composition | | — | 1.1 | 0.0 | — | 1.1 | 0.0 |
| (mmol/g) | | | | | | | |
| Heating | Temperature | — | 230 | 230 | — | 230 | 230 |
| conditions of | (° C.) | | | | | | |
| protective | Time | | 30 | 30 | | 30 | 30 |
| film | (min.) | | | | | | |
| Transistor | Threshold voltage | 1.7 | 0.1 | 1.1 | 1.1 | 0.2 | 0.6 |
| properties | (V) | | | | | | |
| | Electron mobility | 22.3 | 66.7 | 21.2 | 20.8 | 47.2 | 19.3 |
| | (cm²/Vs) | | | | | | |
| | ON/OFF ratio | 9.9 | 9.6 | 9.2 | 9.1 | 8.9 | 8.2 |

The bottom gate-type thin-film transistor element of Example 7 in which the protection film was formed using a composition including a polysiloxane polymer having a SiH group had electron mobility significantly higher than that of the element of Reference Example 3 in which a protective film was not formed. On the other hand, the element of Comparative Example 7 in which the protective film was formed using a composition free of SiH groups was comparable in electron mobility to that of Reference Example 3.

The top gate-type thin-film transistor element of Example 8 had electron mobility significantly higher than that of the element of Reference Example 2 in which an interlayer insulating film was not formed. On the other hand, the element of Comparative Example 2 in which the interlayer insulating film was formed using a composition free of SiH groups was comparable in electron mobility to that of Reference Example 4.

From the results shown in Table 4, it can be seen that even when an oxide forming an oxide semiconductor thin-film contains Sn, the electron mobility of the element is significantly improved by forming a resin layer having a SiH group on the oxide semiconductor thin-film.

### DESCRIPTION OF REFERENCE SIGNS

1 Substrate
2 Gate insulating film
31 Gate layer
4 Oxide semiconductor thin-film
6 Resin film
51, 52, 53, 54 Source/drain electrode
45, 46 Channel region
91, 92, 93, 94 Contact hole

Although the disclosure has been described with respect to only a limited number of embodiments, those skilled in the art, having benefit of this disclosure, will appreciate that various other embodiments may be devised without departing from the scope of the present disclosure. Accordingly, the scope of the invention should be limited only by the attached claims.

What is claimed is:

1. A thin-film transistor element comprising:
a gate layer;
an oxide semiconductor thin-film;
a gate insulating film disposed between the gate layer and the oxide semiconductor thin-film;
a pair of source-drain electrodes electrically connected to the oxide semiconductor thin-film; and
a resin film covering the oxide semiconductor thin-film,
wherein
the oxide semiconductor thin-film contains two or more metal elements selected from the group consisting of indium, gallium, zinc, and tin,
the resin film is in contact with the oxide semiconductor thin-film, and
the resin film includes a compound that contains a SiH group.

2. The thin-film transistor element according to claim 1, wherein an amount of the SiH group in the resin film is 0.001 mmol/g or more.

3. The thin-film transistor element according to claim 1, having an electron mobility of 35 cm²/Vs or more.

4. The thin-film transistor element according to claim 1, wherein the compound contained in the resin film has a SiH group and a polysiloxane structure.

5. The thin-film transistor element according to claim 1, wherein the compound contained in the resin film has a SiH group and a cyclic polysiloxane structure.

6. The thin-film transistor element according to claim 1, wherein the gate insulating film covers a top of the gate layer, and the oxide semiconductor thin-film is disposed on a top of the gate insulating film.

7. The thin-film transistor element according to claim 1, wherein the gate layer is disposed on a top of the gate insulating film, and the gate insulating film is disposed on a top of the oxide semiconductor thin-film.

8. The thin-film transistor element according to claim 1, wherein the oxide semiconductor thin-film contains, as the two or more metal elements, tin and at least one metal element selected from the group consisting of indium, gallium, and zinc.

9. A method for manufacturing a thin-film transistor element, comprising:
applying a composition including a SiH group-containing compound onto an oxide semiconductor thin-film of the thin-film transistor element; and
after the applying, performing heating to form a resin film covering the oxide semiconductor thin-film,
wherein the thin-film transistor element comprises:
a gate layer;
the oxide semiconductor thin-film;
a gate insulating film disposed between the gate layer and the oxide semiconductor thin-film;
a pair of source-drain electrodes electrically connected to the oxide semiconductor thin-film; and
the resin film covering the oxide semiconductor thin-film, and
wherein the oxide semiconductor thin-film contains two or more metal elements selected from the group consisting of indium, gallium, zinc, and tin.

10. The method according to claim 9, wherein the SiH group-containing compound contains 0.1 mmol/g or more of SiH group.

11. The method according to claim 9, wherein a heating temperature in forming the resin film is 190° C. to 450° C.

12. The method according to claim 9, wherein the SiH group-containing compound contains polysiloxane structure.

13. The method according to claim 9, wherein the SiH group-containing compound contains cyclic polysiloxane structure.

14. The method according to claim 9, wherein the SiH group-containing compound is a polymer.

15. The method according to claim 9, wherein the method further comprises forming a contact hole in the resin film by photolithography.

16. The method according to claim 9, wherein the composition is a photosensitive composition of negative-type or positive-type.

17. The method according to claim 9, wherein the composition is a photocurable/thermosetting composition or a thermosetting composition, and the composition has no alkali-solubility.

18. The method according to claim 9, wherein the oxide semiconductor thin-film contains, as the two or more metal elements, tin and at least one metal element selected from the group consisting of indium, gallium, and zinc.

19. The method according to claim 9, wherein the thin-film transistor element has an electron mobility of 35 cm²/Vs or more.
